(19) United States
(12) Patent Application Publication
(10) Pub. No.: US 2004/0037999 A1
(43) Pub. Date: Feb. 26, 2004

(54) Fabrication method

(76) Inventor: Carl C. Phillips, Middlesbrough (GB)

Correspondence Address: SHELDON & MAK, INC, 225 SOUTH LAKE AVENUE, 9TH FLOOR, PASADENA, CA, 91101, US

(21) Appl. No.: 10/461,527

(22) Filed: Jun. 13, 2003

(30) Foreign Application Priority Data
Jun. 14, 2002 (GB) 0213695.0

(51) Int. Cl. B32B 3/10; H01L 23/58; G03F 7/20; G03F 7/16; G03F 7/40

(52) U.S. Cl. 428/131; 428/138; 257/798; 430/315; 430/319; 430/330

(57) ABSTRACT

A method for depositing a feature on a substrate during a device fabrication process, the method comprising the steps of providing a substrate; providing a covering layer on the substrate; providing a surface inhibition layer on the substrate; providing an aperture extending through the surface inhibition layer; providing a via extending from the aperture through the covering layer to the substrate, the via being larger then the aperture such that the surface inhibition layer overhangs the via; depositing a feature material through the aperture onto the substrate to form the feature.

### CROSS-REFERENCE

This application claims priority of United Kingdom Patent Application No. 0213695.0, filed Jun. 14, 2002, the entire contents of which are hereby incorporated by reference.

### BACKGROUND

The present invention relates to solid state electronic device fabrication, and in particular to a method for improving lift off operations.

Solid state electronic devices tend to have very intricate and complex structures, such as conducting tracks, which are provided on a very fine scale and may need to be close to one another. In order to ensure the correct operation of a device it is important that the parts of the device, are as defect free as possible.

Multiple devices tend to be fabricated at the same time on a single wafer and, owing to the manufacturing costs involved, it is important to try and ensure that the yield of correctly functioning devices from a single wafer is as high as possible. Some current device fabrication processes use a method of fabricating features of devices that also tends to produce feature defects. Therefore, a method which reduces such defects would be beneficial.

### SUMMARY

According to a first aspect of the invention, there is provided a method for depositing a feature on a substrate during a device fabrication process, the method comprising the steps of: providing a substrate; providing a covering layer on the substrate; providing a surface inhibition layer on the substrate; providing an aperture extending through the surface inhibition layer; providing a via extending from the aperture through the covering layer to the substrate, the via being larger than the aperture such that the surface inhibition layer overhangs the via; depositing a feature material through the aperture onto the substrate to form the feature. As the aperture of the layer through which material is deposited is smaller than the region in which the feature is created, and as defined by the layer sidewalls, deposited material is not deposited on the sidewalls of the layer and so feature defects are avoided.

The covering layer can be a photoresist. The step of providing a surface inhibition layer can comprise the steps of: applying a developer to the top surface of the covering layer remote from the substrate; and subsequently heating the covering layer. Preferably, the steps of providing the aperture and the via comprise the steps of: providing a mask; irradiating the surface inhibition layer through an aperture in the mask; and applying a developer to remove the irradiated portion of the surface inhibition layer to define the aperture and to remove the covering layer to define the via, the developer having a lower dissolution rate in the surface inhibition layer than in the covering layer.

Preferably, the via extends through the covering layer substantially normal to the substrate, the via being of uniform cross section along its length. Preferably, at least one lateral dimension of the aperture is less then the corresponding lateral dimension of the via.

In a further aspect of the invention there is provided a method for depositing a feature on a substrate during a device fabrication process, the method comprising the steps of: providing a substrate; proving a covering layer on the substrate, the covering layer having a via extending there through, the entrance aperture to the via being smaller than a region on the substrate on which a feature is to be deposited; and creating the feature by depositing a material over the covering layer so that the feature is deposited on the surface of the substrate substantially without depositing the material on side walls of the covering layer adjacent the feature.

In a further aspect of the invention there is provided a solid state electrical device having a feature made according to the method aspect of the invention. In a further aspect of the invention there is provided an intermediate product of a method for depositing a feature during a device fabrication process, the product comprising a substrate layer onto which a feature is to be created; a covering layer above the substrate layer and having a void in which the feature is to exist; and a surface inhibition layer having an aperture extending therethrough, the aperture having a lateral dimension smaller than a corresponding lateral dimension of the void.

The feature can be of a metal. Preferred metals include gold, titanium, platinum and combinations thereof. The feature can be a track, posts or gate finger. The metal can be deposited by evaporation.

The aperture can be formed by overhangs of a surface part of the layer extending beyond lower sidewall parts of the layer. An overhang can be provided on each or either side of the aperture. The lower sidewall parts can be substantially vertical relative to the plane of the substrate. The surface inhibition layer can be an integral part of the layer. The layer can be of positive or negative photoresist material.

The aperture can be defined by an irradiation step using a mask subsequent to forming the surface inhibition layer. The aperture can be defined by an aperture in the mask or by a masking part of a mask. The dimension of the aperture is less than that of the void as defined by the side walls of the intermediate layer and so when the feature is created in the void by deposition, the deposited material is shielded from the sidewalls by the edges of the layer defining the aperture. This helps to avoid the formation of defects on the feature.

### BRIEF DESCRIPTION OF THE DRAWINGS

An embodiment of the invention will now be described, by way of example only, and with reference to the accompanying drawings, in which:

FIGS. 1a to 1i show schematic diagrams illustrating the steps of a prior art fabrication method; and

FIGS. 2a to 2j show schematic diagrams illustrating the steps of a fabrication method of the present invention.

Similar items in different Figures share common reference numerals unless indicated otherwise.

### DETAILED DESCRIPTION

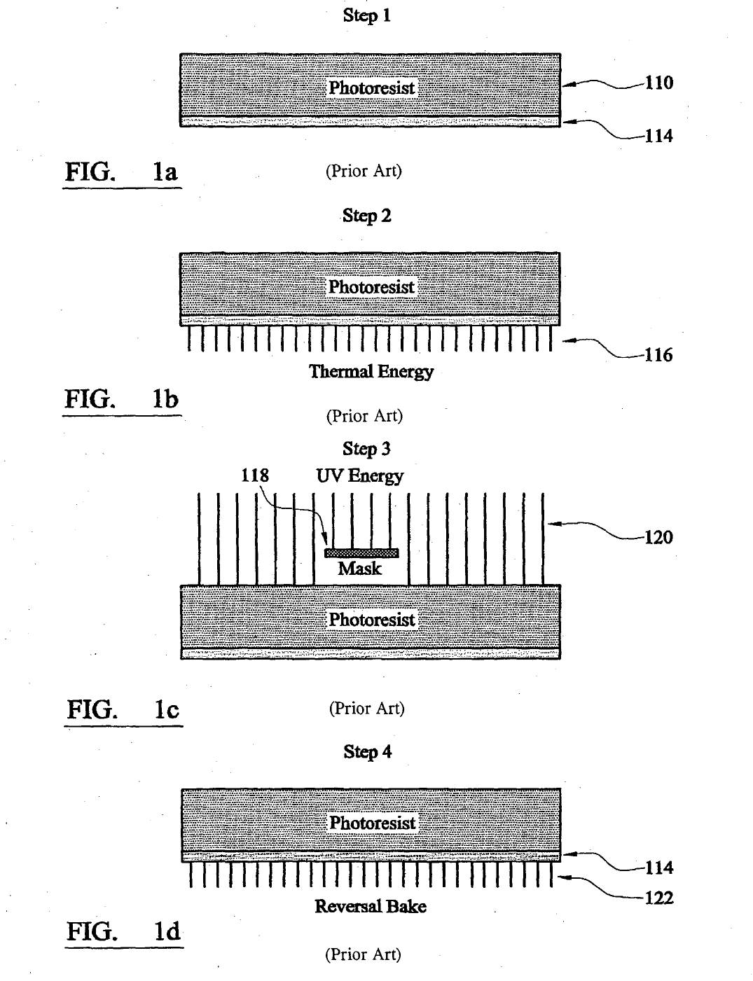

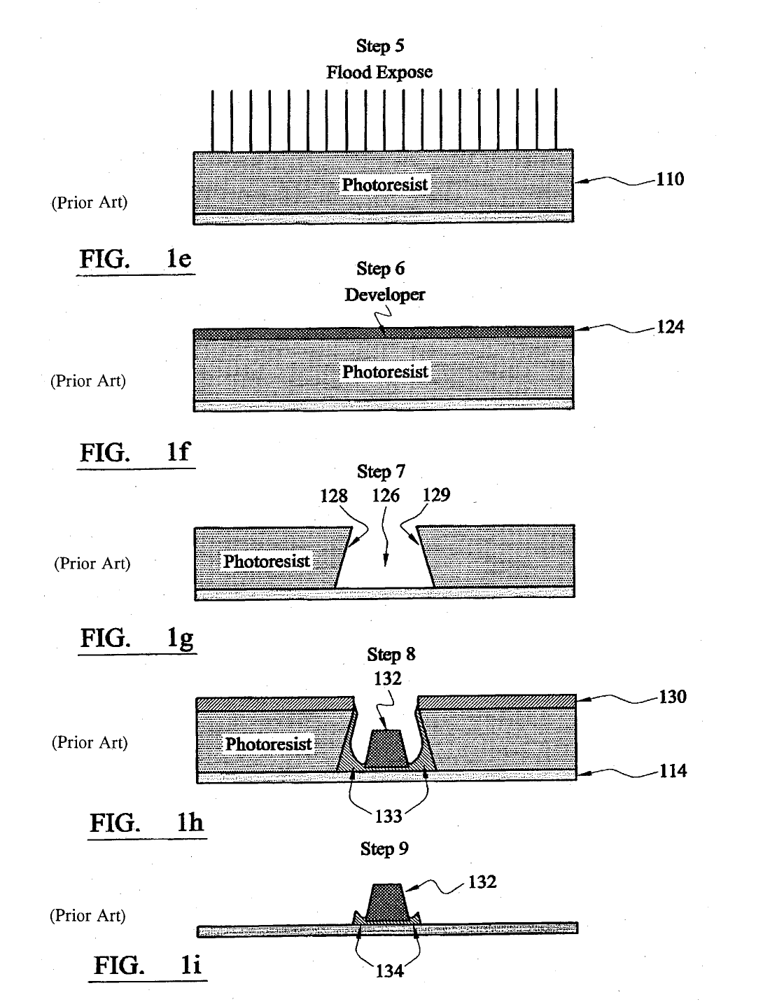

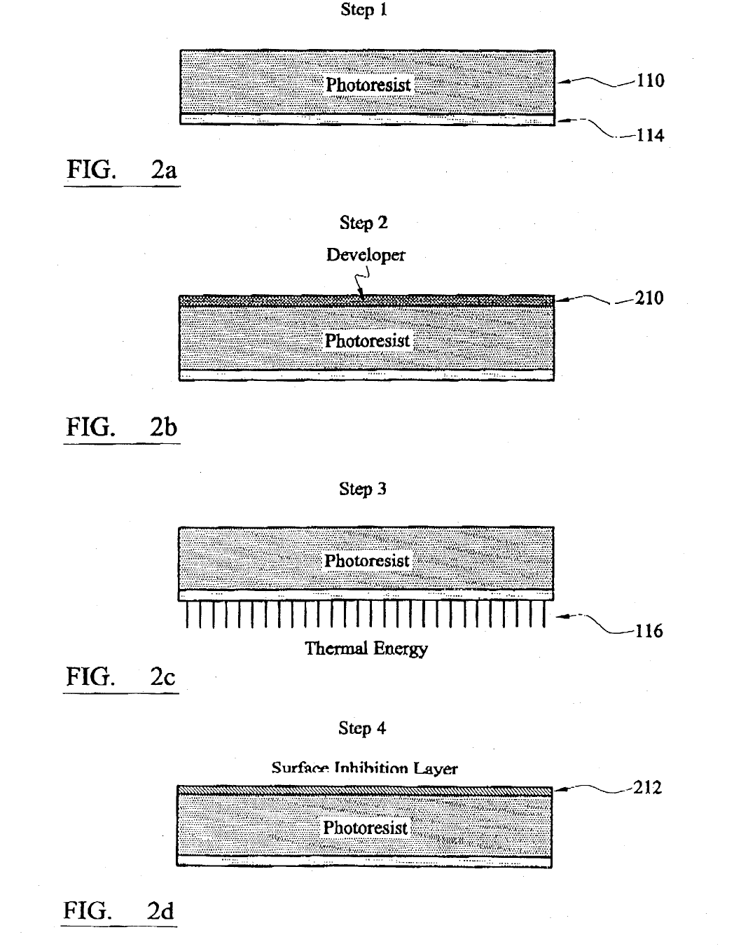

FIGS. 1a to 1i illustrate a number of steps of a conventional solid state electronic device fabrication method which will be described by way of background to the present invention.

In a first step, as shown in FIG. 1a, a layer of positive photoresist material 110, for example Shipley SPR955CM, is deposited on a substrate 114, which can be Si or GaAs. As shown in FIG. 1b, the substrate is then exposed to thermal energy 116 and heated at a temperature of approximately 120° C. for approximately 90 seconds in order to stabilize the solvent content in the resist film 110. In an imaging exposure step illustrated in FIG. 1c, a mask 118 is positioned over an area at which a feature is to be created and the workpiece is exposed to ultraviolet radiation 120 to transfer the mask pattern into the photoresist. A typical exposure level is 50 mJ/cm².

As shown in FIG. 1d, a reverse side of the substrate 114 is then heated 122 using a hot plate providing a temperature of approximately 115° C. for approximately 240 seconds to activate a cross-linking agent in the photoresist. As shown in FIGS. 1e through 1f, an upper surface of the photoresist layer 110 is then exposed to developer solution 124 all over its surface to remove the exposed areas of photoresist. This step creates a via 126, and the photoresist layer has reentrant or negatively sloped sidewalls 128, 129.

A layer of metal 130 is then deposited using evaporation to create a desired metal track feature 132 on the substrate 114 as shown in FIG. 1g. The resist sidewall profile is acceptable in that it allows the photoresist layer to be lifted-off from the substrate in a final lift-off stage to leave the feature 132 as shown in FIG. 1i. However, rotation of the evaporator during the metal deposition stage tends to deposit metal 133 also on the sidewalls 128,129 of the photoresist. This sidewall deposited metal often forms an attachment with the metal track feature 132. As shown in FIG. 1i, after the photoresist layer has been lifted off, metal frill type defects 134 are left on the track.

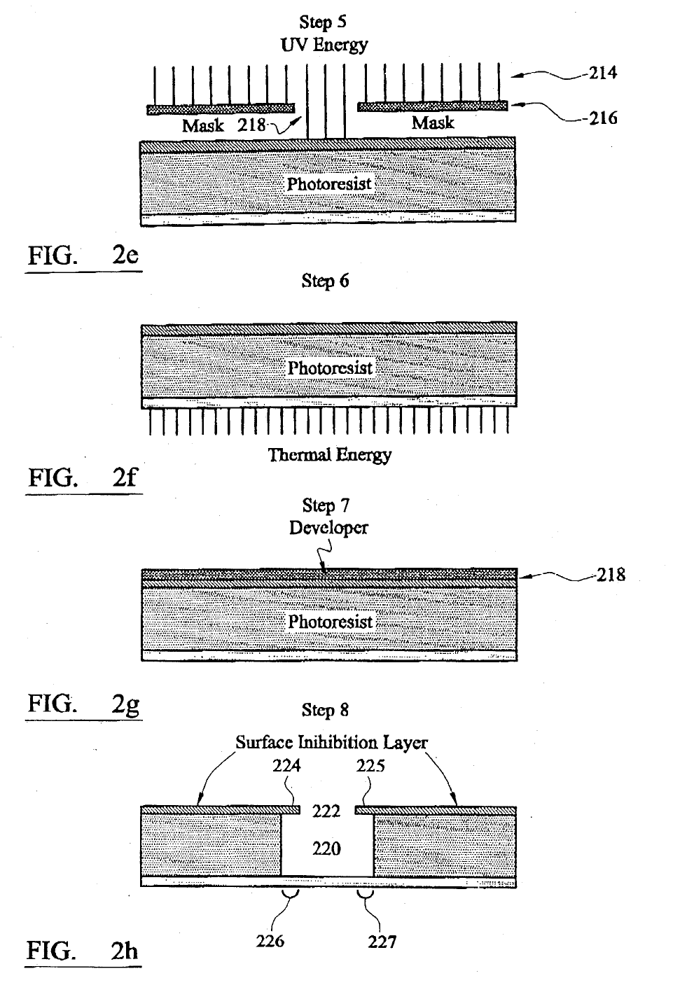

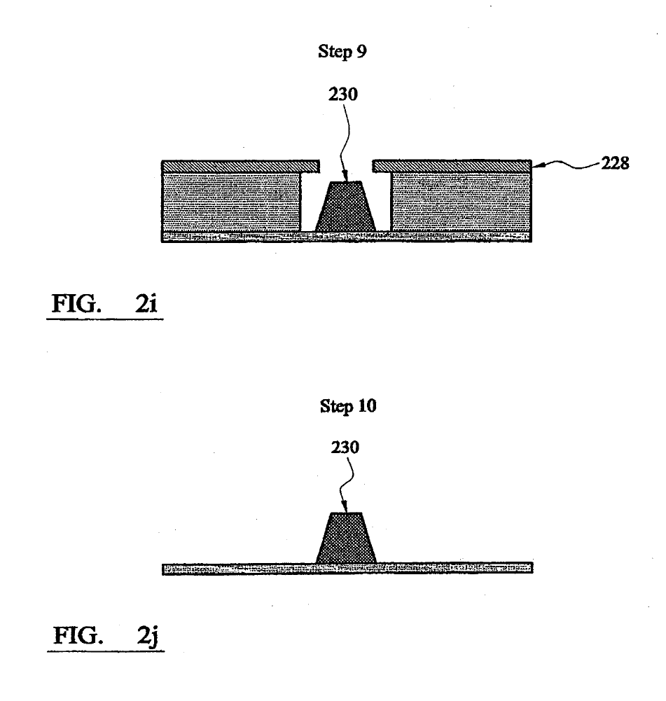

FIGS. 2a to 2j illustrate steps in a solid state electronic device fabrication method of the present invention. A number of the method steps are the same as or similar to those of the conventional method described above and so will not be described again in great detail.

FIG. 2a shows a wafer substrate 114 on which a feature is to be fabricated and onto which a covering layer of positive photoresist 110 has been spun. Shipley SPR955 is an example of a suitable photoresist material. A softbake step corresponding to FIG. 1b is not the next step. Instead, as shown in FIG. 2b, a MIF (Metal Ion Free) developer solution 210, is used to develop the upper surface of the photoresist layer. TMAH ammonium hydroxide is a suitable MIF developer. Alternatively, a MIB (Metal Ion Bearing) developer solution can be used, such as sodium hydroxide. As shown in FIG. 2c, the substrate is then exposed to thermal energy in a softbake step using a hotplate to heat the wafer to a temperature of 120° C. for approximately 90 seconds to create a thin inhibition layer 212 at the upper surface of the photoresist. As shown in FIG. 2d, the inhibition layer is typically approximately 1-3 μm thick. The temperature used in, and the duration of, the heating step determines the thickness or depth of the inhibition layer.

An imaging exposure step is then performed, as shown in FIG. 2e, using ultraviolet radiation 214 and a mask 216 to define an aperture 218 corresponding to an area to be exposed on the inhibition layer which will eventually provide an aperture through which a feature will be formed. The sizing energy Eₛ is increased compared to prior art methods so as to take into account the effect of the inhibition layer. As will be appreciated, the sizing energy is the energy dose required to achieve the mask critical dimension (“CD”, i.e. desired size of the feature). For a positive resist process, energy is increased in order to enlarge a resist space and reduced in order to enlarge a resist line. The opposite is the case for a negative resist. A typical sizing energy dose would be 300 mJ/cm² for 600 ms.

FIG. 2f illustrates a post exposure bake step analogous to FIG. 1d. A hotplate is used to heat the wafer at a temperature of approximately 130° C. for approximately 90 seconds to improve resist contrast and reduce standing waves. Increasing the post exposure bake temperature reduces the resist sensitivity and thereby reduces the critical dimension.

A developer 218 is then used in a developing step, as shown in FIG. 2g, to create a via 220 and an aperture 222 in the inhibition layer corresponding to the area previously exposed by the mask 216. As shown in FIG. 2h, the inhibition layer has portions overhanging the via. The surface inhibition layer slows the dissolution rate of the developer. Once the inhibition layer has been breached the dissolution of the resist increases, resulting in the overhanging side wall profile.

The lateral dimension of the inhibition layer aperture is less than the lateral dimension of the aperture in the photoresist material and so the overhangs 224,225 generate corresponding ‘shadow’ regions 226,227 on the exposed upper surface of substrate 114. The resist side walls are close to vertical with respect to the plane of the substrate and this is controlled by the post exposure bake temperature and time which improves the resist contrast performance.

Metal is deposited so as to create the desired feature 230 on the substrate, as shown in FIG. 2i. The end portions of the inhibition layer over hang the sidewalls of the photoresist layer and so help to prevent metal from being deposited on the side walls. The overhang profile prevents metal migrating around the lip of the profile thereby eliminating sidewall deposition and reducing metal defects on the feature after the photoresist layer is lifted-off. Following the deposition of the metal, the photoresist layer is lifted off from the substrate in a final lift-off stage as shown in FIG. 2j.

The techniques and materials used in a number of the individual steps of the method are considered to be generally known to those of ordinary skill in this art and so have not been described in great detail. However, the details, and particular combination and sequence, of steps used to provide the overhang resulting in an improved lift-off profile, and providing such an improved lift-off profile, are not.

As will be appreciated by those of skill in the art there are a number of other combinations and sequences of method steps which could be used to provide an improved lift-off profile according to the invention and the above is to be considered a preferred example only.

1. A method for depositing a feature on a substrate during a device fabrication process, the method comprising the steps of
providing a substrate;
providing a covering layer on the substrate;
providing a surface inhibition layer on the substrate;
providing an aperture extending through the surface inhibition layer;
providing a via extending from the aperture through the covering layer to the substrate, the via being larger then the aperture such that the surface inhibition layer overhangs the via;
depositing a feature material through the aperture onto the substrate to form the feature.

2. A method as claimed in claim 1, wherein the covering layer is a photoresist.

3. A method as claimed in claim 1, wherein the step of providing a surface inhibition layer comprises the steps of applying a developer to the top surface of the covering layer remote from the substrate; and
subsequently heating the covering layer.

4. A method as claimed in claim 3, wherein the developer is a metal ion free developer solution.

5. A method as claimed in claim 4, wherein the developer is TMAH ammonium hydroxide.

6. A method as claimed in claim 3, wherein the developer is a metal ion bearing developer solution.

7. A method as claimed in claim 6, wherein the developer is sodium hydroxide.

8. A method as claimed in claim 3, wherein the temperature and duration of the heating step are such that the inhibition layer formed is from about 1 μm to about 3 μm thick.

9. A method as claimed in claim 1, wherein the steps of providing the aperture and the via comprise the steps of
providing a mask;
irradiating the surface inhibition layer through an aperture in the mask;
applying a developer to remove the irradiated portion of the surface inhibition layer to define the aperture and to remove the covering layer to define the via, the developer having a lower dissolution rate in the surface inhibition layer than in the covering layer.

10. A method as claimed in claim 1, wherein the via extends through the covering layer substantially normal to the substrate, the via being of uniform cross section along its length.

11. A method as claimed in claim 10, wherein at least one lateral dimension of the aperture is less then a corresponding lateral dimension of the via.

12. A method for depositing a feature on a substrate during a device fabrication process, the method comprising the steps of:
providing a substrate;
providing a covering layer on the substrate, the covering layer having a via extending therethrough, the entrance aperture to the via being smaller than a region on the substrate on which a feature is to be deposited; and
creating a feature by depositing a material over the covering layer so that the feature is deposited on the surface of the substrate substantially without depositing the material on side walls of the covering layer adjacent the feature.

13. A solid state electrical device having a feature made according to the method of claim 1.

14. An intermediate product of a method for depositing a feature during a device fabrication process, the product comprising
a substrate layer onto which a feature is to be created;
a covering layer above the substrate layer and having a void therein which the feature is to exist; and,
a surface inhibition layer having an aperture extending therethrough, the aperture having a lateral dimension smaller than the corresponding lateral dimension of the void.
